(19) United States
(12) Patent Application Publication
(10) Pub. No.: US 2018/0358253 A1
(43) Pub. Date: Dec. 13, 2018

(54) ELECTROSTATIC CHUCK, A PLASMA PROCESSING APPARATUS HAVING THE SAME, AND A METHOD OF MANUFACTURING A SEMICONDUCTOR DEVICE USING THE SAME

(71) Applicant: SAMSUNG ELECTRONICS CO., LTD., SUWON-SI (KR)

(72) Inventors: YOUNGJIN NOH, ANSAN-SI (KR); NAMJUN KANG, BUCHEON-SI (KR); EUNG-SU KIM, SEOUL (KR); SEUNGBO SHIM, SEOUL (KR); SANG-HO LEE, HWASEONG-SI (KR)

(21) Appl. No.: 15/864,293

(22) Filed: Jan. 8, 2018

(30) Foreign Application Priority Data
Jun. 9, 2017 (KR) 10-2017-0072701

(51) Int. Cl. H01L 21/683; H02N 13/00; H01L 21/67; H01J 37/32

(52) U.S. Cl. CPC H01L 21/6833; H02N 13/00; H01L 21/67103; H01L 21/67069; H01J 2237/3321; H01J 2237/2001; H01J 2237/2007; H01J 2237/334; H01J 37/32724

(57) ABSTRACT

An electrostatic chuck includes: a chuck base including a first hole; a first plate on the chuck base, wherein the first plate includes a second hole on the first hole; a first bushing in the first hole; and a porous block in the first bushing, wherein the first bushing contacts the first plate and is disposed adjacent to the porous block.

### CROSS-REFERENCE TO RELATED APPLICATION

This U.S. nonprovisional patent application claims priority under 35 U.S.C § 119 to Korean Patent Application No. 10-2017-0072701 filed on Jun. 9, 2017, the disclosure of which is incorporated by reference herein in its entirety.

### TECHNICAL FIELD

The present inventive concept relates to a semiconductor fabrication facility, and more particularly, to an electrostatic chuck, a plasma processing apparatus having the same, and a method of manufacturing a semiconductor device using the same.

### DISCUSSION OF RELATED ART

In general, semiconductor devices are manufactured through a plurality of unit processes. The unit processes may include a thin-film deposition process, a photolithography process, and an etching process. The etching process may include a dry etching process. The dry etching process may use a plasma reaction and be performed by a dry etching apparatus. The dry etching apparatus may include an electrostatic chuck on which a substrate is placed. The electrostatic chuck may use an electrostatic force to fix the substrate. More specifically, the electrostatic chuck may use an electrostatic force to hold the substrate in place.

### SUMMARY

According to an exemplary embodiment of the present inventive concept, an electrostatic chuck may comprise: a chuck base including a first hole; a first plate on the chuck base, wherein the first plate includes a second hole on the first hole; a first bushing in the first hole; and a porous block in the first bushing, wherein the first bushing contacts the first plate and is disposed adjacent to the porous block.

According to an exemplary embodiment of the present inventive concept, a plasma processing apparatus may comprise: a chamber; an electrostatic chuck disposed in the chamber and configured to load a substrate; and a coolant supply configured to provide the electrostatic chuck with a coolant, wherein the electrostatic chuck may comprise: a chuck base including a first hole; an upper plate on the chuck base, wherein the upper plate includes a second hole on the first hole; a first bushing in the first hole; and a porous block in the first bushing, and wherein the first bushing surrounds a sidewall of the porous block and contacts a bottom surface of the upper plate.

According to an exemplary embodiment of the present inventive concept, a method of manufacturing a semiconductor device may comprise: providing a substrate onto an electrostatic chuck; providing the electrostatic chuck with an electrostatic voltage; and providing the electrostatic chuck with a high frequency power, wherein the electrostatic chuck may comprise: a chuck base including a first hole; a first plate on the chuck base, wherein the first plate includes a second hole on the first hole; a first bushing in the first hole; and a porous block in the first bushing, and wherein the first bushing contacts the first plate and is disposed adjacent to the porous block.

According to an exemplary embodiment of the present inventive concept, an electrostatic chuck may include: a base including a first hole and a second hole coincident with the first hole; and a plate disposed on the base, the plate including a third hole coincident with the second hole, wherein the second hole is disposed between the first hole and the third hole, the base including: a first bushing adjacent to the plate and including a fourth hole having a diameter equal to that of the third hole; and a porous block disposed inside the first bushing between the fourth hole and the second hole.

### BRIEF DESCRIPTION OF THE DRAWINGS

In the drawings, like reference numerals may refer to like elements.

FIG. 1 illustrates a diagram of a plasma processing apparatus according to an exemplary embodiment of the present inventive concept.

FIG. 2 illustrates a cross-sectional view of an electrostatic chuck in section A of FIG. 1, according to an exemplary embodiment of the present inventive concept.

FIG. 3 illustrates an exploded perspective view of the electrostatic chuck of FIG. 2, according to an exemplary embodiment of the present inventive concept.

FIG. 4 illustrates a graph showing a potential difference between a substrate and an electrostatic chuck of FIG. 1, according to an exemplary embodiment of the present inventive concept.

FIG. 5 illustrates a cross-sectional view showing an electric arcing at an electrostatic chuck according to a comparative example.

FIG. 6 illustrates a cross-sectional view showing a discharge plasma at an electrostatic chuck according to a comparative example.

FIG. 7 illustrates a Paschen curve showing a breakdown voltage dependent on a second effective distance between a porous block and an upper plate of FIG. 6.

FIG. 8 illustrates a cross-sectional view of an electrostatic chuck in section A of FIG. 1, according to an exemplary embodiment of the present inventive concept.

FIG. 9 illustrates a cross-sectional view of an electrostatic chuck in section A of FIG. 1, according to an exemplary embodiment of the present inventive concept.

FIG. 10 illustrates a cross-sectional view of an electrostatic chuck in section A of FIG. 1, according to an exemplary embodiment of the present inventive concept.

FIG. 11 illustrates a flow chart showing a method of manufacturing a semiconductor device using the plasma processing apparatus of FIG. 1, according to an exemplary embodiment of the present inventive concept.

### DETAILED DESCRIPTION OF THE EMBODIMENTS

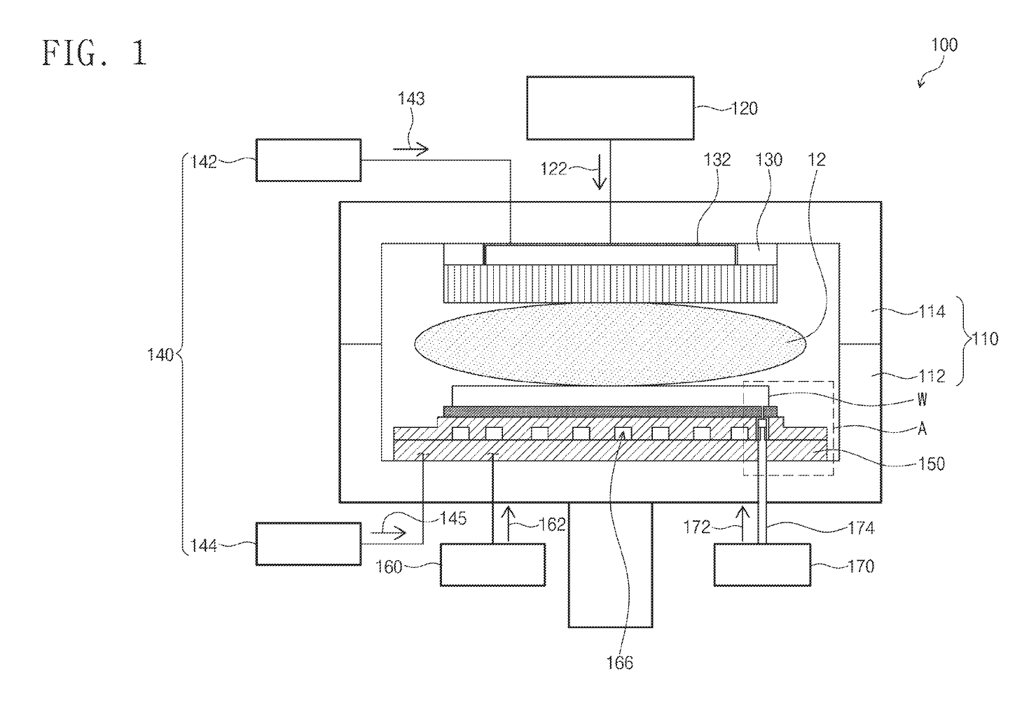

FIG. 1 illustrates a diagram of a plasma processing apparatus 100 according to an exemplary embodiment of the present inventive concept.

Referring to FIG. 1, the plasma processing apparatus 100 may be a capacitively coupled plasma (CCP) etching apparatus. Additionally, the plasma processing apparatus 100 may be an inductively coupled plasma (ICP) etching apparatus or a microwave plasma etching apparatus. In an exemplary embodiment of the present inventive concept, the plasma processing apparatus 100 may include a chamber 110, a reaction gas supply 120, a showerhead 130, a high frequency supply 140, an electrostatic chuck 150, an electrostatic voltage supply 160, and a coolant supply 170.

The chamber 110 may provide a space isolated from the outside. A substrate W may be provided in the chamber 110. The substrate W may include a silicon wafer, but the present inventive concept is not limited thereto. In an exemplary embodiment of the present inventive concept, the chamber 110 may include a lower housing 112 and an upper housing 114. When the substrate W is provided in the chamber 110, the lower housing 112 may be separated from the upper housing 114. For example, the lower housing 112 and the upper housing 114 may be separated to allow the substrate W to be placed in the chamber 110. When the substrate W experiences a treatment process, the lower housing 112 may be coupled to the upper housing 114.

The reaction gas supply 120 may supply the chamber 110 with a reaction gas 122. The reaction gas 122 may etch the substrate W or a thin layer on the substrate W. For example, the reaction gas 122 may include CH3 or SF6, but the present inventive concept is not limited thereto. Additionally, the reaction gas 122 may deposit a thin layer on the substrate W.

The showerhead 130 may be provided in the upper housing 114. The showerhead 130 may be engaged with the reaction gas supply 120. The showerhead 130 may spray the reaction gas 122 onto the substrate W. The showerhead 130 may include an upper electrode 132. The upper electrode 132 may be engaged with the high frequency supply 140.

The high frequency supply 140 may provide the upper electrode 132 and the electrostatic chuck 150 with a high frequency power from outside the chamber 110. In an exemplary embodiment of the present inventive concept, the high frequency supply 140 may include a first high frequency power supply 142 and a second high frequency power supply 144. The first high frequency power supply 142 may be engaged with the upper electrode 132. The first high frequency power supply 142 may provide the upper electrode 132 with a source high frequency power 143. The source high frequency power 143 may induce a plasma 12 in the chamber 110. The second high frequency power supply 144 may be engaged with the electrostatic chuck 150. The second high frequency power supply 144 may provide the electrostatic chuck 150 with a bias high frequency power 145. The bias high frequency power 145 may concentrate the plasma 12 onto the substrate W. The substrate W may be etched proportional to the bias high frequency power 145. Additionally, when the upper electrode 132 is not provided in the showerhead 130, the source high frequency power 143 may be provided to the electrostatic chuck 150. When an etching depth of the substrate W or the thin layer on the substrate W exceeds a predetermined value, the source high frequency power 143 and the bias high frequency power 145 may be provided in a pulse mode.

The electrostatic chuck 150 may be installed in the lower housing 112. The substrate W may be placed on the electrostatic chuck 150. The substrate W may be provided on a central portion of the electrostatic chuck 150. When the plasma 12 is induced on the electrostatic chuck 150, the electrostatic chuck 150 may be cooled down by a cooling fluid provided into one or more cooling fluid holes 166.

The electrostatic voltage supply 160 may supply the electrostatic chuck 150 with an electrostatic voltage 162. When the plasma 12 is induced on the substrate W, the substrate W may be held in a fixed position on the electrostatic chuck 150 by the electrostatic voltage 162. As an example, the substrate W may be fixed on the electrostatic chuck 150 by the Johnsen-Rahbek or Coulomb effect of the electrostatic voltage 162.

A coolant 172 may be provided through a supply line 174 into the electrostatic chuck 150. The coolant 172 may pass through the electrostatic chuck 150 and may then be provided onto a bottom surface of the substrate W. When the plasma 12 heats the substrate W, the coolant 172 may cool the substrate W. For example, the coolant 172 may decrease the temperature of the substrate W. For example, the coolant 172 may include a helium (He) gas.

The electrode chuck 150, which is capable of providing the coolant 172 to the bottom surface of the substrate W, will be described in detail hereinafter.

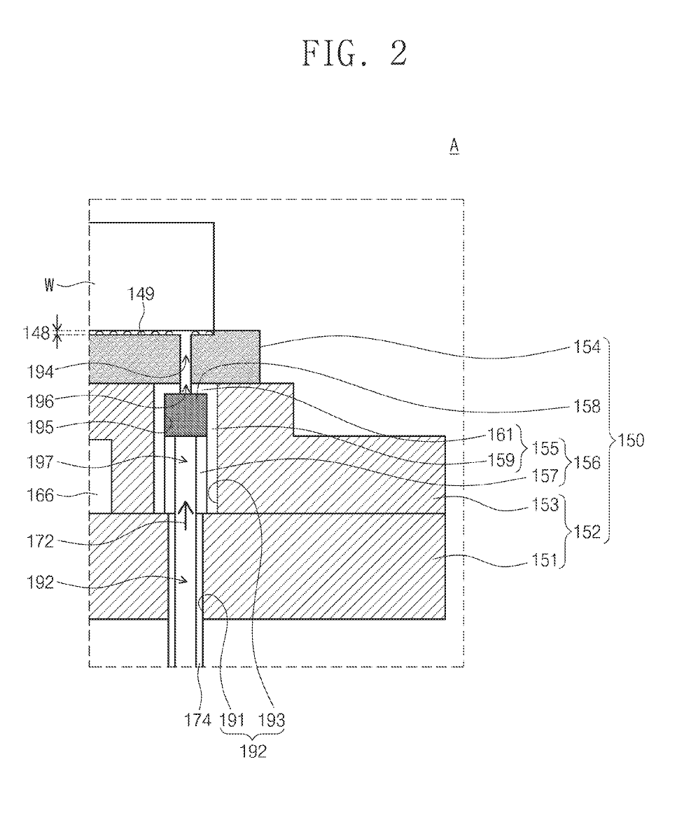

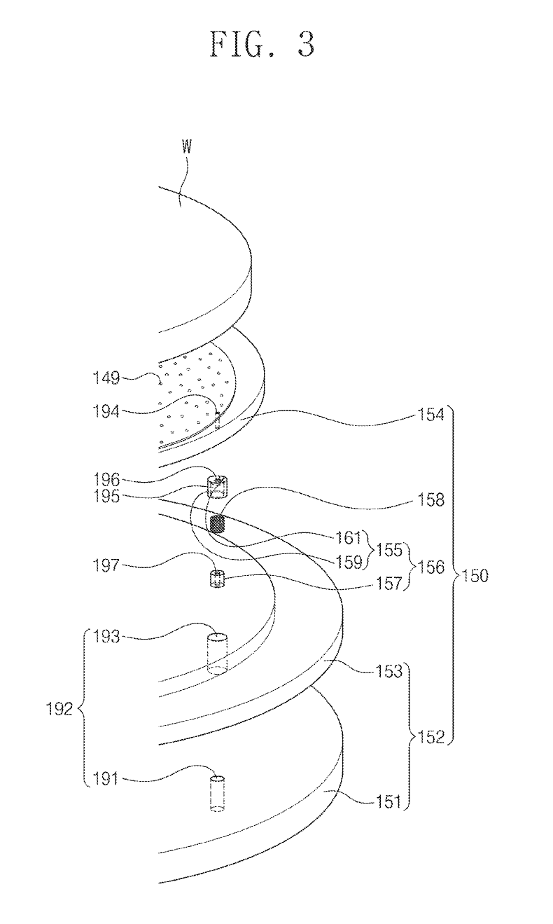

FIG. 2 illustrates a cross-sectional view of the electrostatic chuck 150 in section A of FIG. 1, according to an exemplary embodiment of the present inventive concept. FIG. 3 illustrates an exploded perspective view of the electrostatic chuck 150 of FIG. 2, according to an exemplary embodiment of the present inventive concept.

Referring to FIGS. 2 and 3, the electrostatic chuck 150 may include a chuck base 152, an upper plate 154, bushings 156, and a porous block 158.

The chuck base 152 may be wider or larger than the substrate W, in a plan view. The chuck base 152 may include a lower hole 192 penetrating therethrough. The lower hole 192 may be disposed at or near an edge of the chuck base 152. The supply line 174 may be connected to the lower hole 192. The lower hole 192 may receive the coolant 172 through the supply line 174. The lower hole 192 may include a first lower hole 191 and a second lower hole 193 that are spatially connected to each other. The chuck base 152 may include aluminum or its alloy. The chuck base 152 may include a first lower plate 151 and a second lower plate 153.

The first lower plate 151 may be provided with the first lower hole 191. The first lower hole 191 may be provided in the first lower plate 151 with the supply line 174 or with a connector coupled to the supply line 174. For example, the first lower hole 191 may have a diameter ranging from about 3 mm to about 4 mm. When the substrate W has a diameter of about 300 mm, the first lower plate 151 may have a diameter of more than about 3,200 mm and a thickness of about 13 mm.

The second lower plate 153 may lie on the first lower plate 151. The second lower plate 153 may have a thickness of about 21 mm. The second lower plate 153 may have a diameter equal to that of the first lower plate 151. The second lower plate 153 may be provided with the second lower hole 193. The second lower hole 193 may be aligned with the first lower hole 191. For example, the second lower hole 193 may be disposed above the first lower hole 191 to permit the coolant 172 to pass from the first lower hole 191 to the second lower hole 193. The second lower hole 193 may have a diameter greater than that of the first lower hole 191. The diameter of the second lower hole 193 may be about 7 mm. When the second lower hole 193 is provided in plural, the first lower hole 191 may include branch holes that horizontally connect the plurality of second lower holes 193. The cooling fluid holes 166 may be formed between the first lower plate 151 and the second lower plate 153. For example, the cooling fluid holes 166 may be formed at an interface between the first lower plate 151 and the second lower plate 153.

The upper plate 154 may lie on the second lower plate 153. The substrate W may be provided on the upper plate 154. The upper plate 154 may include an Al₂O₃ ceramic dielectric, and may have a thickness of about 1.7 mm. When the substrate W is provided on the upper plate 154, the upper plate 154 may insulate the substrate W from the chuck base 152. The upper plate 154 may include an upper hole 194. The upper hole 194 may be disposed on the lower hole 192. The coolant 172 may pass through the lower and upper holes 192 and 194, and may then be provided onto the bottom surface of the substrate W.

In addition, the upper plate 154 may include dielectric protrusions 149. The dielectric protrusions 149 may be disposed on a top surface of the upper plate 154, and may be in contact with or may face the bottom surface of the substrate W. The dielectric protrusions 149 may have a size or height ranging from about 10 μm to about 100 μm. The dielectric protrusions 149 may create a gap 148 between the bottom surface of the substrate W and the top surface of the upper plate 154. The gap 148 may have a height equal to the height of the dielectric protrusions 149. When the coolant 172 is provided through the upper hole 194 into the gap 148, the coolant 172 may cool the substrate W. The upper hole 194 may have a diameter less than that of the second lower hole 193. The diameter of the upper hole 194 may be about 0.3 mm.

The bushings 156 may be provided in the second lower hole 193 of the second lower plate 153. For example, the bushings 156 may include an Al₂O₃ ceramic material. The bushings 156 may extend from a top surface of the first lower plate 151 to a bottom surface of the upper plate 154 along an inner wall of the second lower hole 193. In an exemplary embodiment of the present inventive concept, the bushings 156 may include a first bushing 155 and a second bushing 157.

The first bushing 155 may cover the second bushing 157 and the porous block 158. The first bushing 155 may surround a sidewall of the second bushing 157 and a sidewall of the porous block 158. The second bushing 157 may have an inner diameter of about 7 mm and an outer diameter of about 5 mm. The second bushing 157 may be disposed in a lower portion of the first bushing 155. The first bushing 155 may be an outer bushing, and the second bushing 157 may be an inner bushing. In other words, the second bushing 157 may be disposed inside the first bushing 155. The porous block 158 may be disposed in an upper portion of the first bushing 155. In an exemplary embodiment of the present inventive concept, the first bushing 155 may include a ring segment 159 and a capping segment 161.

The ring segment 159 may surround the sidewall of the porous block 158 and the sidewall of the second bushing 157. The ring segment 159 may be coupled to an edge of the capping segment 161. The ring segment 159 may extend from the edge of the capping segment 161 to the first lower plate 151. The ring segment 159 may have a first bushing hole 195. The first bushing hole 195 may have a diameter of about 5 mm. The ring segment 159 may have a height and/or a thickness ranging from about 1 cm to about 2 cm.

The capping segment 161 may cover the ring segment 159 and the porous block 158. The capping segment 161 may have a top surface in contact with the bottom surface of the upper plate 154. The capping segment 161 may have a thickness of about 0.8 mm. The capping segment 161 may have a second bushing hole 196. The second bushing hole 196 may be aligned with the upper hole 194. The second bushing hole 196 may have a diameter equal to that of the upper hole 194. The diameter of the second bushing hole 196 may be about 0.3 mm. The second bushing hole 196 may connect the first bushing hole 195 to the upper hole 194. The coolant 172 may be provided onto the bottom surface of the substrate W through a third bushing hole 197 of the second bushing 157, the porous block 158 in the first bushing hole 195, the second bushing hole 196, and the upper hole 194.

The top surface of the capping segment 161 may be in contact with the bottom surface of the upper plate 154. The top surface of the capping segment 161 may be adhered through an adhesive to the bottom surface of the upper plate 154. An increase in area of the capping segment 161 may increase an adhesion area between the capping segment 161 and the bottom surface of the upper plate 154. The increased adhesion area between the upper plate 154 and the capping segment 161 may result in reduced leakage of the coolant 172. As such, the capping segment 161 may enhance adhesion reliability between the upper plate 154 and the first bushing 155.

The second bushing 157 may be disposed on the first lower plate 151 adjacent to the first lower hole 191. The second bushing 157 may support the porous block 158. The second bushing 157 may be in contact with the supply line 174 provided in the first lower hole 191. The second bushing 157 may have a shape different from that of the first bushing 155. The second bushing 157 may have the third bushing hole 197 and have a ring shape. The coolant 172 in the supply line 174 may be provided onto the bottom surface of the substrate W through the third bushing hole 197, the first bushing hole 195, the second bushing hole 196, and the upper hole 194. The third bushing hole 197 may have a diameter less than that of the first lower hole 191 and greater than that of the upper hole 194. For example, the second bushing 157 may have a diameter of about 5 mm, and the third bushing hole 197 may have a diameter of about 2 mm.

The porous block 158 may be disposed between the second bushing 157 and the capping segment 161. The porous block 158 may buffer a pressure of the coolant 172 in the first bushing hole 195. The porous block 158 may include a dielectric material. The porous block 158 may have a circular pillar shape with a diameter of about 5 mm and a height of about 5 mm. For example, the porous block 158 may include a ceramic (e.g., Al₂O₃) having a porosity density ranging from about 50% to about 60%.

Referring back to FIG. 1, when the plasma 12 is produced in the chamber 110, a potential difference may be induced between the substrate W and the electrostatic chuck 150. The potential difference may be due to the source high frequency power 143 and the bias high frequency power 145. The potential difference may be a high voltage.

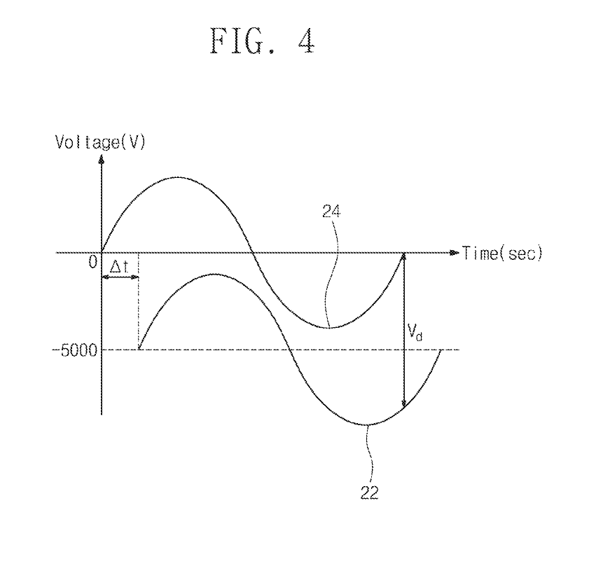

FIG. 4 shows a potential difference Vd between the substrate W and the electrostatic chuck 150 of FIG. 1, according to an exemplary embodiment of the present inventive concept.

Referring to FIGS. 1 and 4, when the substrate W has a first induction voltage 22 and the electrostatic chuck 150 has a second induction voltage 24, the potential difference Vd may correspond to a difference between the first induction voltage 22 and the second induction voltage 24. The first induction voltage 22 may be produced from the source high frequency power 143, and the second induction voltage 24 may be produced from the bias high frequency power 145. The first induction voltage 22 may be less than the second induction voltage 24. For example, the first induction voltage 22 may be about 5 kV less than the second induction voltage 24.

The potential difference Vd may change with time. The potential difference Vd may depend on frequencies of the first and second induction voltages 22 and 24, wavelengths of the first and second induction voltages 22 and 24, and/or a time delay Δt between the first and second induction voltages 22 and 24. For example, when the first and second induction voltages 22 and 24 have the same frequency and/or the same wavelength, and the first induction voltage 22 has a time delay Δt with respect to the second induction voltage 24, the potential difference Vd may increase by more than about 5 kV. An increase in the potential difference Vd may generate an electric arcing and a discharge plasma of the coolant 172. The electric arcing and plasma discharge will be described hereinafter.

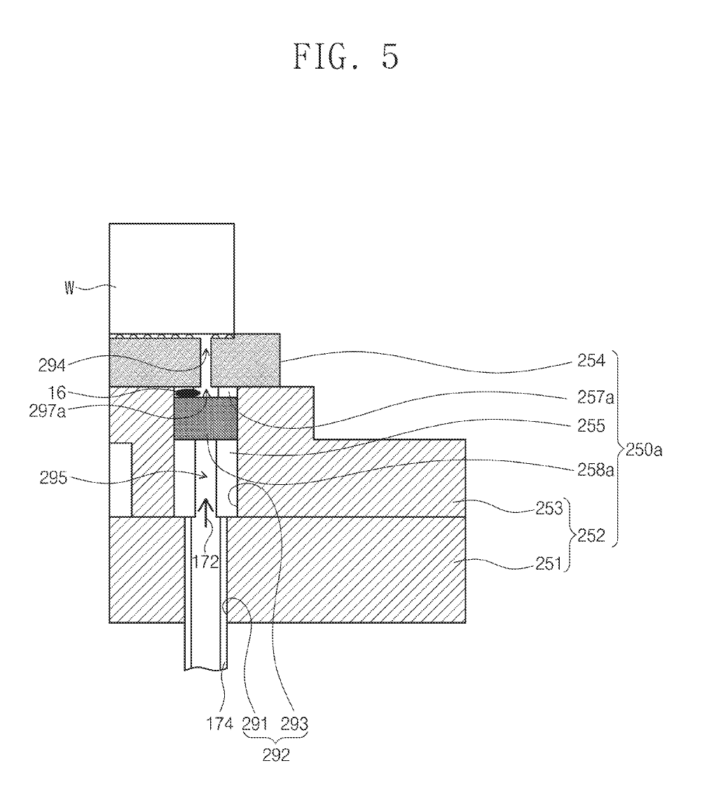

FIG. 5 shows an electric arcing 16 at an electrostatic chuck 250a according to a comparative example.

Referring to FIG. 5, the electrostatic chuck 250a may include a flat bushing 257a. The flat bushing 257a may induce the electric arcing 16. The flat bushing 257a may be disposed on a porous block 258a. A lower bushing 255 may be disposed below the porous block 258a. A first lower plate 251 of a chuck base 252 may support the lower bushing 255 and the porous block 258a. The chuck base 252 may include a second lower plate 253 whose inner sidewall is exposed to a second lower hole 293 among lower holes 292. The porous block 258a may have a sidewall in contact with the inner sidewall of the second lower plate 253. The coolant 172 may be provided into the lower bushing 255 through a supply line 174 provided in a first lower hole 291 of the lower holes 292. The coolant 172 may fill a first bushing hole 295 of the lower bushing 255, the porous block 258a, an upper bushing hole 297a of the flat bushing 257a, and an upper hole 294 of an upper plate 254. The upper bushing hole 297a may have a diameter greater than that of the upper hole 294.

The electric arcing 16 may be mostly generated between a bottom surface of the flat bushing 257a and a top surface of the porous block 258a. Even if the bottom surface of the flat bushing 257a and the top surface of the porous block 258a are bonded to each other by an adhesive, the electric arcing 16 may still be generated by the coolant 172 in the porous block 258a adjacent to the bottom surface of the flat bushing 257a. The electric arcing 16 may be an overcurrent that flows through the coolant 172 between the substrate W and the second lower plate 253. When the electric arcing 16 is generated, the flat bushing 257a, the second lower plate 253, and the porous block 258a may be damaged. The electric arcing 16 may reduce lifetimes of the flat bushing 257a, the second lower plate 253, and the porous block 258a.

The electric arcing 16 may be generated depending on a first effective distance between the substrate W and the second lower plate 253. The first effective distance may correspond to a sum of a thickness of the upper plate 254, a thickness of the flat bushing 257a, and a radius of the flat bushing 257a. A generation frequency of the electric arcing 16 may be in inverse proportion to the first effective distance. For example, the generation frequency of the electric arcing 16 may increase with the reduction of the first effective distance between the substrate W and the second lower plate 253. In contrast, the generation frequency of the electric arcing 16 may decrease with the increase of the first effective distance between the substrate W and the second lower plate 253.

Referring back to FIG. 2, compared to the flat busing 257a of FIG. 5, the first bushing 155 may increase the first effective distance between the substrate W and the second lower plate 153. This is so, because the first bushing 155 includes the ring segment 159 below the capping segment 161. Therefore, the first effective distance may increase. The first effective distance of the electrostatic chuck 150 may be greater than that of the electrostatic chuck 250a by a height of the ring segment 159. For example, when the first effective distance of the electrostatic chuck 250a is about 5 mm, the first effective distance of the electrostatic chuck 150 including the first bushing 155 may be about 15 mm to about 25 mm. The first bushing 155 may have an arc suppression voltage greater than that of the flat bushing 257a. The arc suppression voltage may be calculated by multiplying together the first effective distance, the dielectric strength of air (e.g., 3.0*10⁶ V/m), and a safety factor (e.g., 0.5). For example, when the flat bushing 257a has an arc suppression voltage of about 7.5 kV, the first bushing 155 may have an arc suppression voltage of about 22.5 kV. Accordingly, the first bushing 155 may minimize or prevent the occurrence of the electric arcing 16.

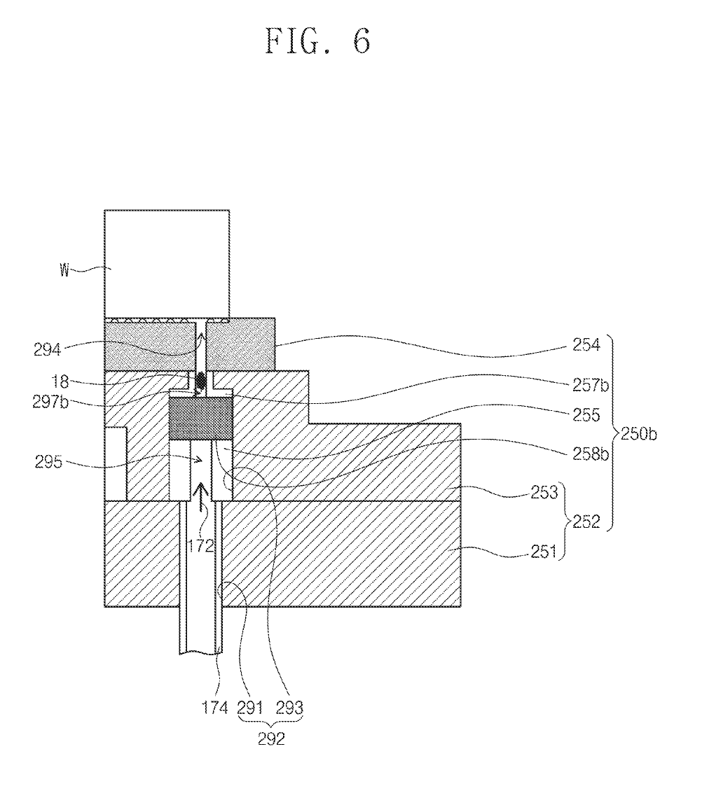

FIG. 6 shows a discharge plasma 18 at an electrostatic chuck 250b according to a comparative example.

Referring to FIG. 6, the electrostatic chuck 250b may include a protruding bushing 257b. The protruding bushing 257b may induce the discharge plasma 18, and may thus have decreased lifetime. The protruding bushing 257b may be thicker or larger than the flat busing 257a of FIG. 5. The protruding bushing 257b may separate an upper plate 254 and a porous block 258b to be farther away from each other, compared to the flat bushing 257a of FIG. 5. A chuck base 252, the upper plate 254, and a lower bushing 255 may be substantially the same as those discussed with reference to FIG. 5.

The discharge plasma 18 may be mostly generated in an upper bushing hole 297b of the protruding bushing 257b. The discharge plasma 18 may be an electric discharge of the coolant 172 provided in the upper bushing hole 297b. The discharge plasma 18 may damage the protruding bushing 257b and the porous block 258b. The discharge plasma 18 may be generated depending on a second effective distance between the substrate W and the porous block 258b. The second effective distance may correspond to a linear distance between the substrate W and the porous block 258b. The second effective distance may be calculated by adding a thickness of the protruding bushing 257b to a thickness of the upper plate 254.

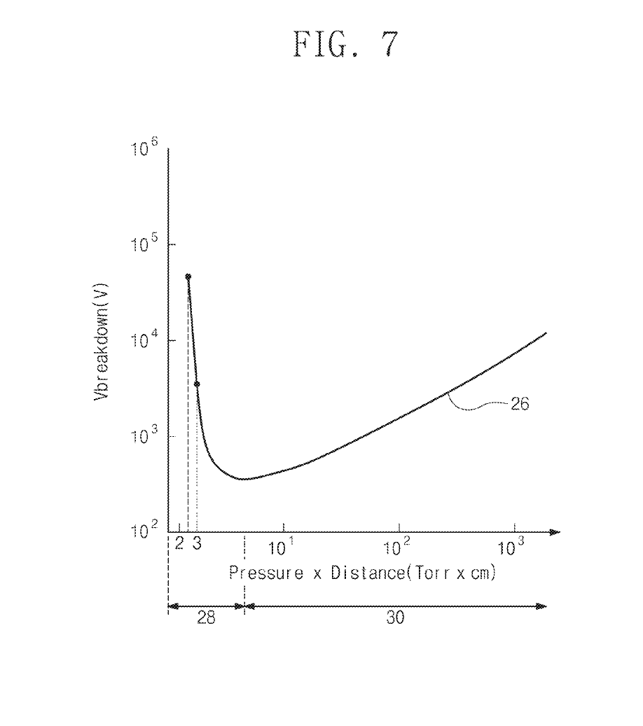

FIG. 7 illustrates a Paschen curve showing a breakdown voltage 26 dependent on the second effective distance between the upper plate 254 and the porous block 258b of FIG. 6. In FIG. 7, a horizontal axis may express a log-scale of the product of a pressure of the coolant 172 multiplied by the second effective distance between the substrate W and the porous block 258b, and a longitudinal axis may denote the breakdown voltage.

Referring to FIG. 7, when the coolant 172 is helium, at an abrupt slope range 28, the breakdown voltage 26 of the coolant 172 may be in inverse proportion to the second effective distance between the upper plate 254 and the porous block 258b. The breakdown voltage 26 may have a negative slope at the abrupt slope range 28 and a positive slope at a gentle slope range 30. When about 10 Torr is the pressure of the coolant 172 and more than about 3 mm is the second effective distance between the substrate W and the porous block 258b, the breakdown voltage 26 of the electrostatic chuck 250b may be about 6 kV. The breakdown voltage 26 may increase with a reduction in the distance between the upper plate 254 and the porous block 258b. For example, the discharge plasma 18 may decrease with a reduction in the distance between the upper plate 254 and the porous block 258b.

Referring back to FIG. 2, compared to the protruding bushing 257b of FIG. 6, the first bushing 155 may decrease the second effective distance between the substrate W and the porous block 158. The capping segment 161 of the first bushing 155 may minimize or reduce the second effective distance between the substrate W and the porous block 158. For example, when the second effective distance between the porous block 158 and the substrate W is less than about 2.5 mm, the breakdown voltage 26 of the electrostatic chuck 150 may be more than about 70 kV. The second bushing hole 196 of FIG. 2 may have a diameter less than that of the upper bushing hole 297a of FIG. 5 and a height less than that of the upper bushing hole 297b of FIG. 6. The second bushing hole 196 of FIG. 2 may minimize or reduce a space where the electric arcing 16 and the discharge plasma 18 can be generated. Accordingly, the first bushing 155 may minimize or prevent the occurrence of the electric arcing 16 and the discharge plasma 18.

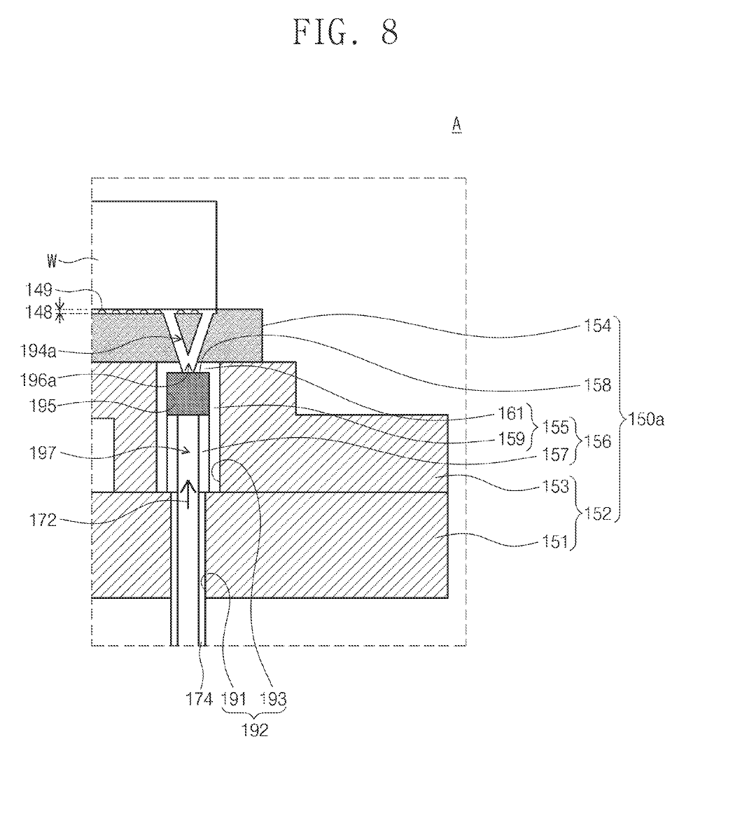

FIG. 8 illustrates a cross-sectional view of the electrostatic chuck in section A of FIG. 1, according to an exemplary embodiment of the present inventive concept.

Referring to FIG. 8, an electrostatic chuck 150a may be configured such that the first bushing 155 has a V-shaped second bushing hole 196a and the upper plate 154 has a V-shaped upper hole 194a. The upper hole 194a of the upper plate 154 and the second bushing hole 196a of the capping segment 161 may be disposed in a different direction from that of the first bushing hole 195 of the ring segment 159. The upper hole 194a and the second bushing hole 196a may be inclined with respect to the substrate W and/or the chuck base 152. The upper hole 194a and the second bushing hole 196a may increase the first effective distance, while not increasing the second effective distance. In this case, the second effective distance may correspond to the linear distance between the substrate W and the porous block 158. An increase in the first effective distance may increase the arc suppression voltage. The porous block 158, the bushings 156, and the upper plate 154 may each have an increased lifetime. The chuck base 152 and the second bushing 157 may be substantially the same as those discussed with reference to FIG. 2.

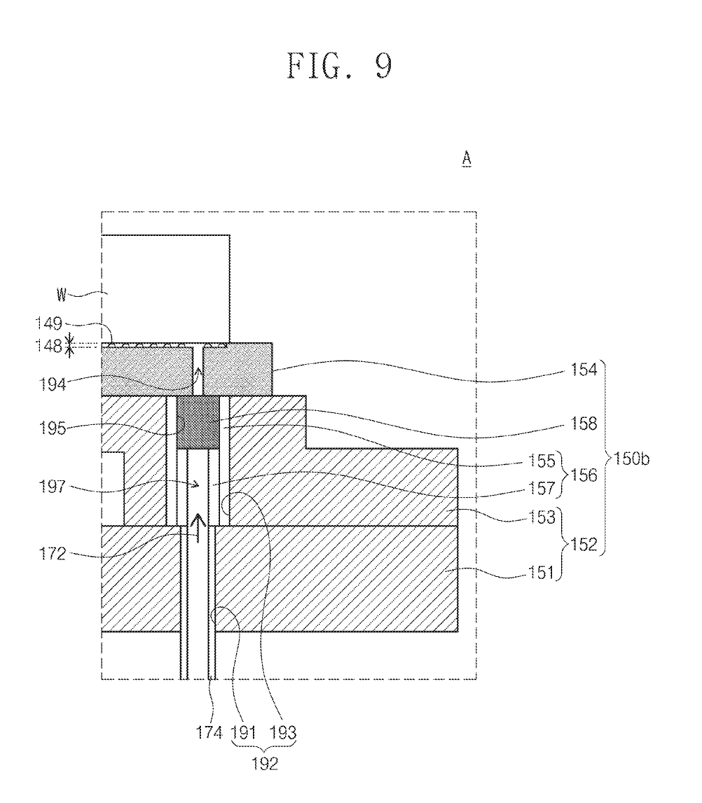

FIG. 9 illustrates a cross-sectional view of the electrostatic chuck in section A of FIG. 1, according to an exemplary embodiment of the present inventive concept.

Referring to FIG. 9, an electrostatic chuck 150b may include the porous block 158 in contact with the bottom surface of the upper plate 154. The porous block 158 may be disposed in an upper portion of the first busing hole 195 of the first bushing 155. The first bushing 155 among the bushings 156 may be in contact with the bottom surface of the upper plate 154 at sides of the porous block 158. The capping segment 161 of FIG. 2 is not included in FIG. 9. The first bushing 155 may extend from the bottom surface of the first lower plate 151 to the bottom surface of the upper plate 154. The porous block 158 may be connected to the upper hole 194. The first bushing 155 may have a thickness equal to a sum of that of the porous block 158 and that of the second bushing 157. The first bushing 155 may increase the first effective distance between the substrate W and the chuck base 152, and decrease the second effective distance between the substrate W and the porous block 158. The first bushing 155 and the porous block 158 may increase the arc suppression voltage and the breakdown voltage. The upper plate 154, the first bushing 155, and the porous block 158 may each have an increased lifetime. The chuck base 152, the second lower plate 153, and the second bushing 157 may be substantially the same as those discussed with reference to FIG. 2.

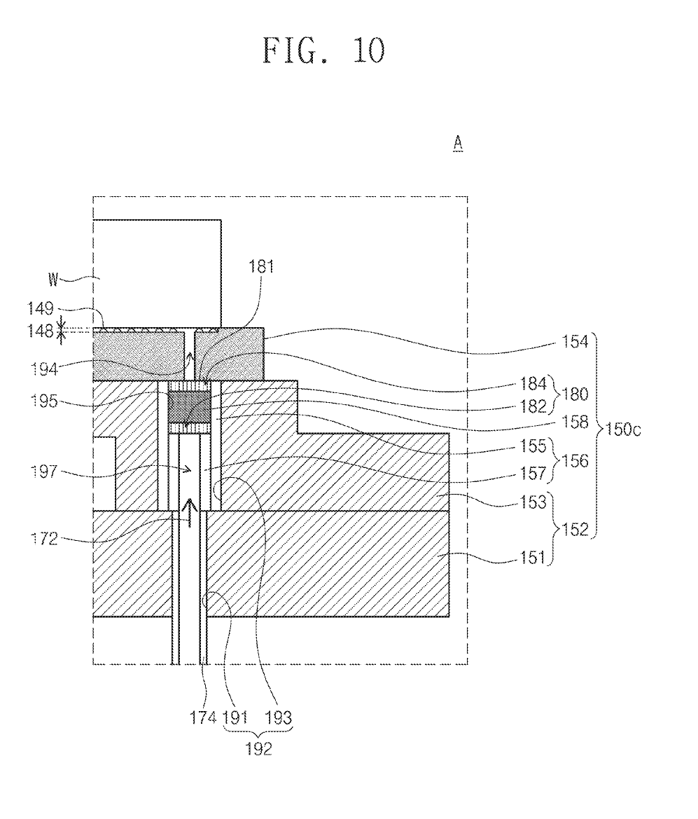

FIG. 10 shows the electrostatic chuck of FIG. 1, according to an exemplary embodiment of the present inventive concept.

Referring to FIG. 10, an electrostatic chuck 150c may include capillary blocks 180. The capillary blocks 180 may be placed on top and bottom sides of the porous block 158. The capillary blocks 180 may each have a plurality of capillary tubes 181. The capillary tubes 181 may extend in the same direction as the first bushing hole 195 and the upper hole 194. The capillary tubes 181 may decrease a space where the discharge plasma 18 of FIG. 6 is generated in the first bushing 155. The capillary blocks 180 may increase the first effective distance and/or the second effective distance. The capillary blocks 180 may increase the arc suppression voltage and/or the breakdown voltage of the electrostatic chuck 150c. In an exemplary embodiment of the present inventive concept, the capillary blocks 180 may include a lower capillary block 182 and an upper capillary block 184.

The lower capillary block 182 may be disposed between the porous block 158 and the second bushing 157 among the bushings 156. The lower capillary block 182 may increase a first effective distance between the substrate W and the chuck base 152.

The upper capillary block 184 may be disposed between the porous block 158 and the upper plate 154. The upper capillary block 184 may increase the first effective distance. The upper capillary block 184 may decrease a second effective distance. The second effective distance may be a distance between the bottom surface of the substrate W and a top surface of the upper capillary block 184. The upper capillary block 184 may prevent or minimize the discharge plasma 18. The upper plate 154, the first bushing 155, and the porous block 158 may each have an increased lifetime.

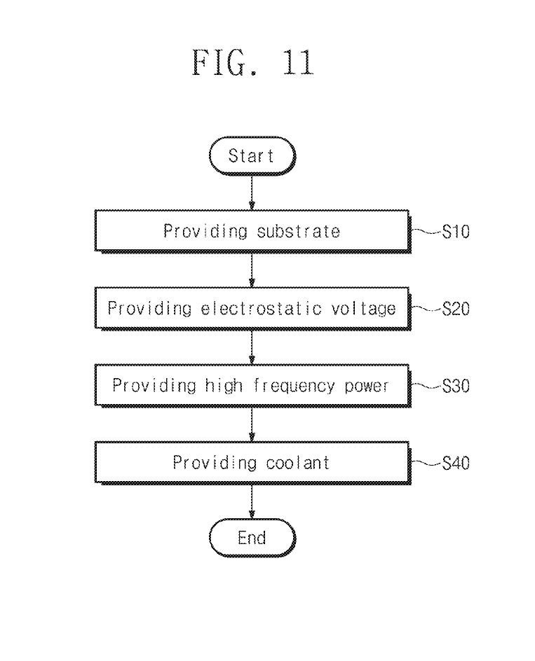

FIG. 11 is a flow chart illustrating a method of manufacturing a semiconductor device using the plasma processing apparatus 100 of FIG. 1, according to an exemplary embodiment of the present inventive concept.

Referring to FIG. 11, a method of manufacturing a semiconductor device may include providing the substrate W (S10), providing the electrostatic voltage 162 (S20), providing the high frequency power (S30), and providing the coolant 172 (S40).

When the upper and lower housings 114 and 112 are separated from each other, a robot arm may provide the substrate W onto the electrostatic chuck 150 (S10).

When the upper and lower housings 114 and 112 are coupled to each other, the electrostatic voltage supply 160 may provide the electrostatic chuck 150 with the electrostatic voltage 162 (S20).

The high frequency supply 140 may provide the high frequency power to the upper electrode 132 and/or the electrostatic chuck 150 (S30). The first high frequency power supply 142 may supply the upper electrode 132 with the source high frequency power 143, and the second high frequency power supply 144 may supply the electrostatic chuck 150 with the bias high frequency power 145. The source high frequency power 143 and the bias high frequency power 145 may be pulsed at a frequency of several to several tens of Hz. The reaction gas supply 120 may provide the showerhead 130 with the reaction gas 122. The substrate W may be etched. When the substrate W becomes more deeply etched, the bias high frequency power 145 may increase in pulse magnitude. Additionally, the reaction gas 122 may deposit a thin layer on the substrate W in a chemical vapor deposition (CVD) process.

The coolant supply 170 may supply the coolant 172 into the electrostatic chuck 150 (S40). The coolant 172 may be provided onto the bottom surface of the substrate W through the lower hole 192 of the chuck base 152, the porous block 158, and the upper hole 194 of the upper plate 154. The bottom surface of the substrate W may receive the coolant 172 from the electrostatic chuck 150 having the arc suppression voltage of more than about 22.5 kV and the breakdown voltage of more than about 70 kV.

After the substrate W is processed, the lower and upper housings 114 and 112 may be separated from each other. The robot arm may unload the substrate W from the electrostatic chuck 150.

According to an exemplary embodiment of the present inventive concept, the electrostatic chuck may increase the arc suppression voltage and the breakdown voltage by using the bushing that surrounds a sidewall of the porous block in a lower hole of the chuck base and that is in contact with the upper plate on the chuck base.

While the present inventive concept has been described with reference to exemplary embodiments thereof, it will be understood to those skilled in the art that various changes and modifications may be made thereto without departing from the scope of the present inventive concept.

1. An electrostatic chuck, comprising:
a chuck base including a first hole;
a first plate on the chuck base, wherein the first plate includes a second hole on the first hole;
a first bushing in the first hole; and
a porous block in the first bushing,
wherein the first bushing contacts the first plate and is disposed adjacent to the porous block.

2. The electrostatic chuck of claim 1, wherein the first bushing comprises a capping segment that is disposed between the first plate and the porous block and includes a third hole aligned with the second hole.

3. The electrostatic chuck of claim 2, wherein the third hole has a diameter equal to that of the second hole.

4. The electrostatic chuck of claim 2, wherein the second and third holes are slanted with respect to the first hole.

5. The electrostatic chuck of claim 2, wherein the second and third holes form a V shape.

6. The electrostatic chuck of claim 2, further comprising a second bushing in the first bushing and adjacent to the porous block,
wherein the first bushing further comprises a ring segment that is coupled to an edge of the capping segment, and the first bushing surrounds a sidewall of the porous block and a sidewall of the second bushing.

7. The electrostatic chuck of claim 6, wherein
the first hole comprises a first hole part and a second hole part,
the chuck base comprises:
a second plate including the first hole part; and
a third plate on the second plate and including the second hole part, and
wherein the ring segment extends from the edge of the capping segment to the second plate.

8. The electrostatic chuck of claim 1, wherein the porous block is in contact with the first plate.

9. The electrostatic chuck of claim 1, further comprising a capillary block in the first bushing.

10. The electrostatic chuck of claim 9, wherein the capillary block comprises:
a first capillary block between the porous block and the first plate; and
a second capillary block opposite the first capillary block.

11. A plasma processing apparatus, comprising:
a chamber;
an electrostatic chuck disposed in the chamber and configured to load a substrate; and
a coolant supply configured to provide the electrostatic chuck with a coolant,
wherein the electrostatic chuck comprises:
a chuck base including a first hole;
an upper plate on the chuck base, wherein the upper plate includes a second hole on the first hole;
a first bushing in the first hole; and
a porous block in the first bushing, and
wherein the first bushing surrounds a sidewall of the porous block and contacts a bottom surface of the upper plate.

12. The plasma processing apparatus of claim 11, wherein
the first hole comprises a first lower hole and a second lower hole,
the chuck base comprises:
a first lower plate including the first lower hole; and
a second lower plate including the second lower hole between the first lower hole and the second hole, and
the first bushing is disposed in the second lower hole.

13. The plasma processing apparatus of claim 12, wherein the electrostatic chuck further comprises a second bushing in the first bushing, and the second bushing is between the porous block and the first lower plate.

14. The plasma processing apparatus of claim 13, further comprising a supply line connected between the coolant supply and the electrostatic chuck,
wherein the supply line contacts the second bushing.

15. The plasma processing apparatus of claim 11, wherein the first bushing comprises:
a capping segment that is disposed between the porous block and the upper plate and includes a third hole aligned with the second hole; and
a ring segment that is coupled to an edge of the porous block and surrounds the sidewall of the porous block.

16-20. (canceled)

21. An electrostatic chuck, comprising:
a base including a first hole and a second hole coincident with the first hole; and
a plate disposed on the base, the plate including a third hole coincident with the second hole,
wherein the second hole is disposed between the first hole and the third hole, the base including:
a first bushing adjacent to the plate and including a fourth hole having a diameter equal to that of the third hole; and
a porous block disposed inside the first bushing between the fourth hole and the second hole.

22. The electrostatic chuck of claim 21, further comprising:
a second bushing disposed inside the first bushing, wherein the second bushing is disposed between the porous block and the first hole.

23. The electrostatic chuck of claim 22, wherein the second hole is disposed between sidewalls of the second bushing.

24. The electrostatic chuck of claim 22, wherein a diameter of the second hole is equal to that of an opening in the second bushing.

25. The electrostatic chuck of claim 24, wherein the diameter of the second hole is greater than that of the third hole.
